(19) United States
(12) Patent Application Publication
(10) Pub. No.: US 2001/0034095 A1
(43) Pub. Date: Oct. 25, 2001

(54) Method of forming n-channel and p-channel MOS field effect transistors over a single semiconductor substrate

(75) Inventor: Tomoko Matsuda, Tokyo (JP)

Correspondence Address: YOUNG & THOMPSON, 745 SOUTH 23RD STREET 2ND FLOOR, ARLINGTON, VA, 22202

(73) Assignee: NEC Corporation

(21) Appl. No.: 09/756,744

(22) Filed: Jan. 10, 2001

(30) Foreign Application Priority Data
Jan. 11, 2000 (JP) 2000-002973

(51) Int. Cl. H01L 21/8238; H01L 21/425

(52) U.S. Cl. 438/231; 438/528

(57) ABSTRACT

The present invention provides a method of forming a diffusion region in a semiconductor region. The method comprises the steps of: carrying out a first ion-implantation of a first impurity of a first conductivity type into the semiconductor region to form an ion-implanted region which is in non-amorphous state, wherein first type clusters of the first impurity are formed in the ion-implanted region; carrying out a second ion-implantation of a second impurity of the first conductivity type into the ion-implanted region, wherein second type clusters of the first and second impurities are formed in the ion-implanted region; and carrying out a heat treatment for activating the first and second impurities in the ion-implanted region to change the ion-implanted region into a diffusion region.

### BACKGROUND OF THE INVENTION

The present invention relates to a method of forming a semiconductor device, and more particularly to a method of forming both a p-channel MOS field effect transistor and an n-channel MOS field effect transistor over a single semiconductor substrate concurrently, wherein plural kinds of impurity are implanted in the same selected regions of the single semiconductor substrate to form shallow junctions of the diffusion regions.

It has been known that the p-channel MOS field effect transistor and the n-channel MOS field effect transistor are concurrently formed over the same semiconductor substrate, wherein BF₂ and/or B are implanted into source and drain regions of the p-channel MOS field effect transistor. An anneal is carried out to activate the implanted BF₂ and/or B in an oxygen atmosphere, wherein a preferable oxygen concentration of the oxygen atmosphere is in the range of about 0.05 to 1 percent by volume. If the oxygen concentration of the oxygen atmosphere is above the preferable range, then an oxygen-enhanced diffusion is caused to increase a junction depth of the source and drain regions of the p-channel MOS field effect transistor, and also cause a deposition of B in a surface oxide film, whereby a sheet resistance of the source and drain regions of the p-channel MOS field effect transistor is increased.

The above anneal is carried out not only to the source and drain regions of the p-channel MOS field effect transistor but also to the source and drain regions of the n-channel MOS field effect transistor concurrently. If P is solely implanted into the source and drain regions of the n-channel MOS field effect transistor, then the following problems are caused. If the preferable oxygen concentration of the oxygen atmosphere with respect to the source and drain regions of the p-channel MOS field effect transistor is in the range of about 0.05 to 1 percent by volume, and further if no cover oxide film is formed over the source and drain regions of the n-channel MOS field effect transistor, then a remarkable outward diffusion of P is caused. It is necessary for suppressing an outward diffusion of P that the oxygen concentration is increased up to at least about 20 percents by volumes.

The above first conventional method has the following disadvantages. If the cover film is provided which covers the surface of the substrate in carrying out the annealing process for activation to the ion-implanted source and drain regions, then an enhanced diffusion of B is caused. To avoid this enhanced diffusion of B, the cover film does not extends over the source and drain regions of the p-channel MOS field effect transistor, whilst the source and drain regions of the n-channel MOS field effect transistor are covered by the cover film. The annealing is carried out in the oxygen atmosphere at an oxygen concentration in the range of 0.05 to 1 percent by volume. This means it unnecessary to selectively form the cover film, which covers only the source and drain regions of the n-channel MOS field effect transistor, for which purpose the cover film is first entirely formed over the surface of the substrate, and then the cover film is then patterned by the lithography process to form a mask pattern and subsequent anisotropic etching process by use of the mask pattern. Namely, additional processes are necessary, and the number of the fabrication process steps is increased.

In Japanese laid-open patent publication No. 11-186188, the second conventional method is disclosed. No additional process is carried out. Notwithstanding, an effective suppression to a phenomenon of tailing of an impurity concentration profile is realized by forming double diffusion regions for source and drain regions, wherein plural kinds of ions different in atomic weight or atomic number are sequentially implanted into the source and drain regions, provided that the ions having a larger atomic weight or a larger atomic number are first implanted into the source and drain regions to cause imperfect amorphousness of the source and drain regions before the other ions having a smaller atomic weight or a smaller are subsequently implanted into the imperfectly amorphous source and drain regions, thereby suppressing that the smaller atomic weight or atomic number ions are extra-deeply implanted. As a result, the tailing of the impurity concentration profile is suppressed, and a shallow junction is realized.

The above-described second conventional method has the following disadvantages. In order to realize the shallow junction of the source and drain regions, the larger atomic weight ions are first implanted into the source and drain regions to cause the amorphousness of the source and drain regions before the smaller atomic weight ions are subsequently implanted into the source and drain regions in amorphous state to suppress the excess-deep implantation of the smaller atomic weight ions. Namely, the ion-implantation process for implanting the larger atomic weight ions is necessary as an additional process to cause the amorphousness of the source and drain regions.

In the above circumstances, it had been required to develop a novel method of forming a semiconductor device having a p-channel MOS field effect transistor and an n-channel MOS field effect transistor, each of which has shallow junction source and drain regions free from the above problem.

### SUMMARY OF THE INVENTION

Accordingly, it is an object of the present invention to provide a novel method of forming a semiconductor device having a p-channel MOS field effect transistor and an n-channel MOS field effect transistor, free from the above problems.

It is a further object of the present invention to provide a novel method of forming a semiconductor device having a p-channel MOS field effect transistor and an n-channel MOS field effect transistor, each of which has shallow junction source and drain regions without any additional process.

It is a still further object of the present invention to provide a novel method of forming a semiconductor device having a p-channel MOS field effect transistor and an n-channel MOS field effect transistor, without selective forming any cover film.

It is yet a further object of the present invention to provide a novel method of forming a semiconductor device having a p-channel MOS field effect transistor and an n-channel MOS field effect transistor, each of which has shallow junction source and drain regions with a reduced sheet resistance.

The present invention provides a method of forming a diffusion region in a semiconductor region. The method comprises the steps of carrying out a first ion-implantation of a first impurity of a first conductivity type into the semiconductor region to form an ion-implanted region which is in non-amorphous state, wherein first type clusters of the first impurity are formed in the ion-implanted region; carrying out a second ion-implantation of a second impurity of the first conductivity type into the ion-implanted region, wherein second type clusters of the first and second impurities are formed in the ion-implanted region; and carrying out a heat treatment for activating the first and second impurities in the ion-implanted region to change the ion-implanted region into a diffusion region.

The above and other objects, features and advantages of the present invention will be apparent from the following descriptions.

### BRIEF DESCRIPTION OF THE DRAWINGS

Preferred embodiments according to the present invention will be described in detail with reference to the accompanying drawings.

FIGS. 1A through 1H are fragmentary cross sectional elevation views illustrative of semiconductor devices in sequential steps involved in a first novel fabrication method in a first embodiment in accordance with the present invention.

FIGS. 2A through 2K are fragmentary cross sectional elevation views illustrative of semiconductor devices in sequential steps involved in a second novel fabrication method in a second embodiment in accordance with the present invention.

### DISCLOSURE OF THE INVENTION

The present invention provides a method of forming a diffusion region in a semiconductor region. The method comprises the steps of: carrying out a first ion-implantation of a first impurity of a first conductivity type into the semiconductor region to form an ion-implanted region which is in non-amorphous state, wherein first type clusters of the first impurity are formed in the ion-implanted region; carrying out a second ion-implantation of a second impurity of the first conductivity type into the ion-implanted region, wherein second type clusters of the first and second impurities are formed in the ion-implanted region; and carrying out a heat treatment for activating the first and second impurities in the ion-implanted region to change the ion-implanted region into a diffusion region.

It is preferable that the heat treatment is carried out in an oxygen atmosphere having an oxygen concentration in the range of 0.05 percents by volume to 1 percent by volume.

It is also preferable that the first impurity comprises at least one selected from the groups consisting of As, Ar and Ge, and the second impurity comprises P, and the first type and second type clusters suppress an outward diffusion of the second impurity of P in the heat treatment.

It is also preferable that the second impurity comprises at least one selected from the groups consisting of As, Ar and Ge, and the first impurity comprises P, and the first type and second type clusters suppress an outward diffusion of the first impurity of P in the heat treatment.

It is also preferable that the first impurity comprises As, and the second impurity comprises P, and the first ion-implantation is carried out at an implantation energy of less than 15 keV and a dose of less than 1E15 cm⁻².

It is also preferable that the diffusion region comprises an n-type extension region which extends in a p-type pocket implantation region which further extends in an upper region of an n-type deep source/drain region in a p-type semiconductor region. It is further preferable that the p-type semiconductor region comprises a p-well region.

It is also preferable that the diffusion region comprises an n-type deep source/drain region in a p-type semiconductor region, and an upper region of the an n-type deep source/drain region overlapping an n-type extension region which extends in a p-type pocket implantation region. It is further preferable that the p-type semiconductor region comprises a p-well region.

It is also preferable that the diffusion region comprises an n-type deep source/drain region in a p-type semiconductor region. It is further preferable that the p-type semiconductor region comprises a p-well region.

### Preferred Embodiment

First Embodiment:

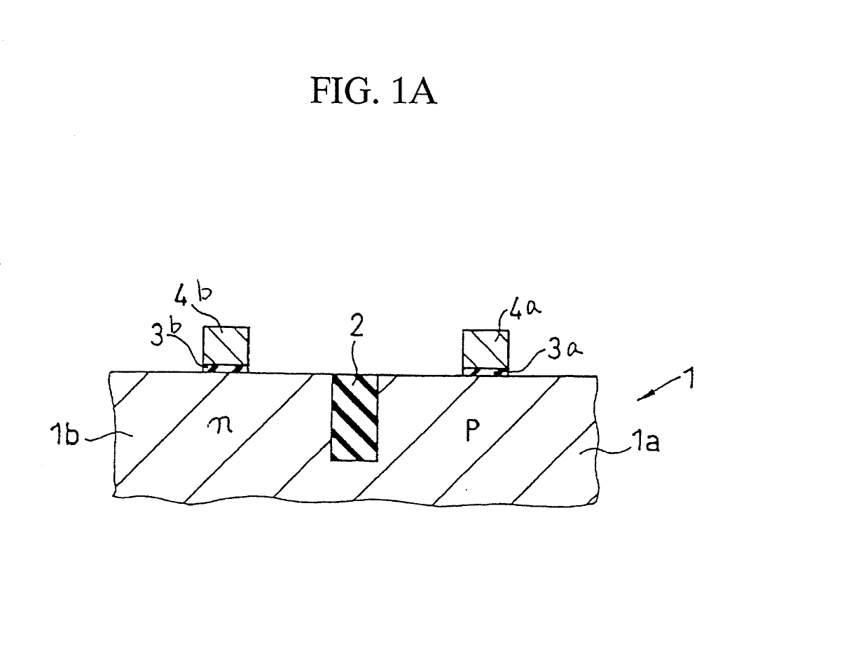

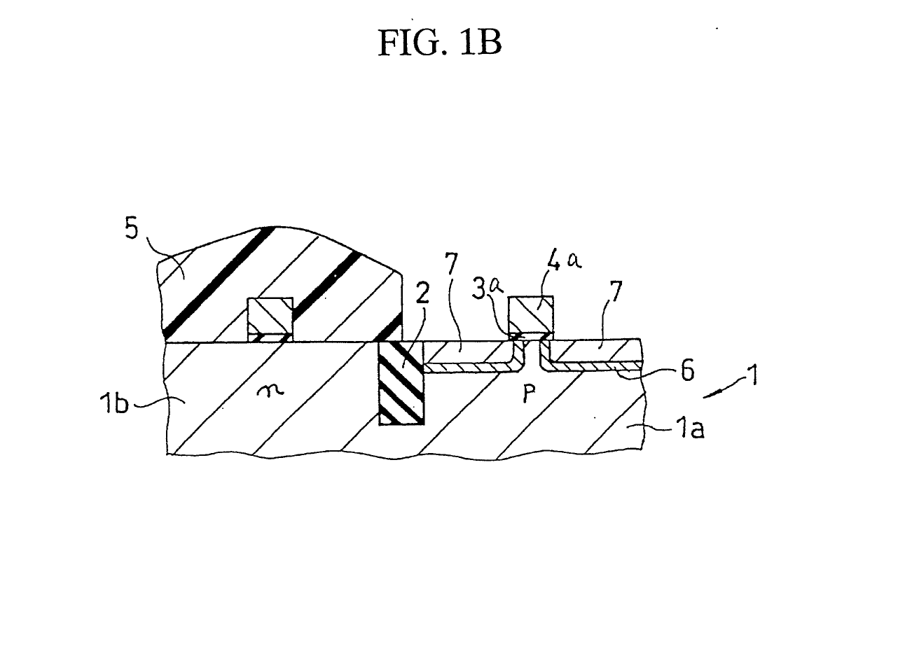

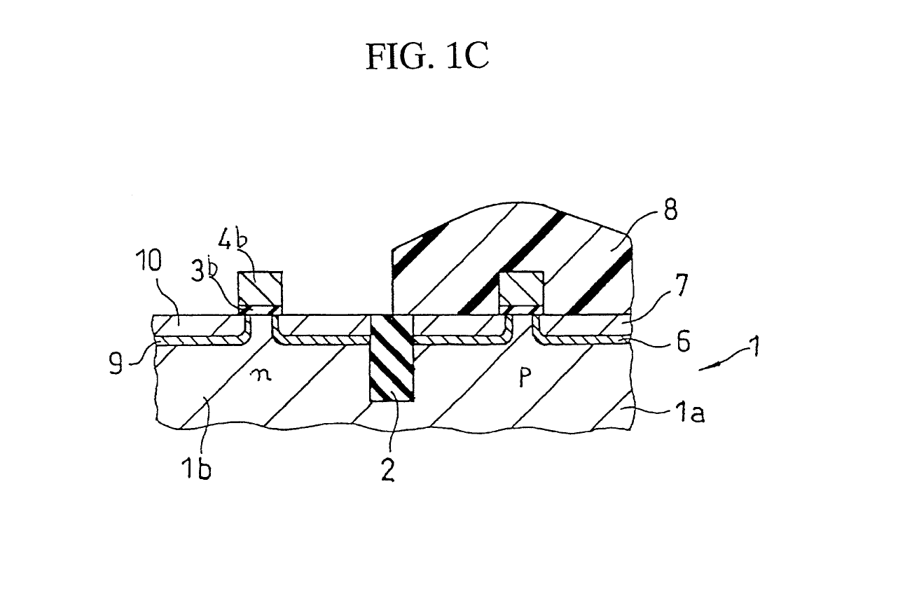

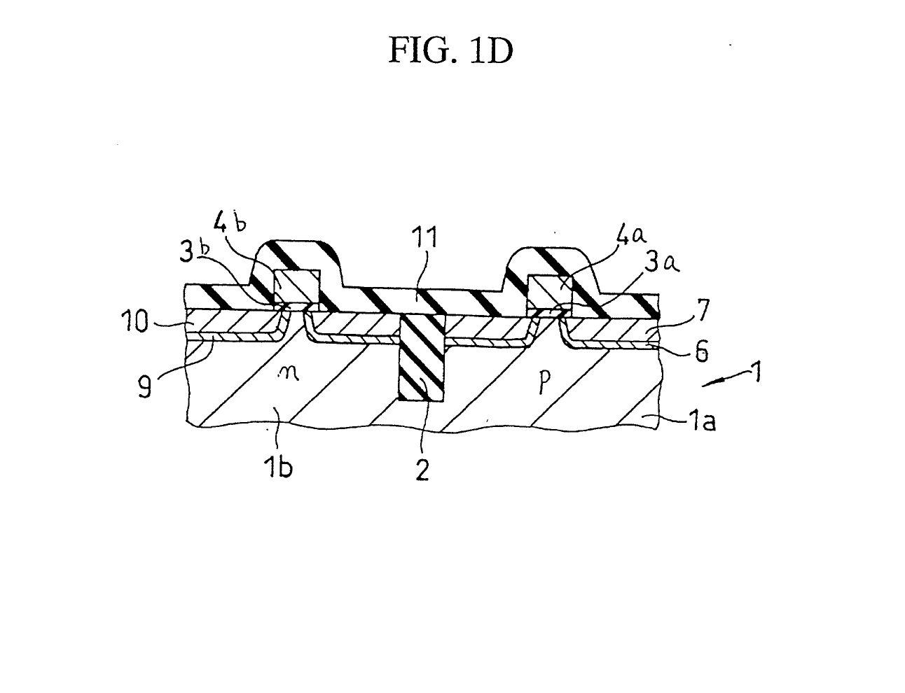

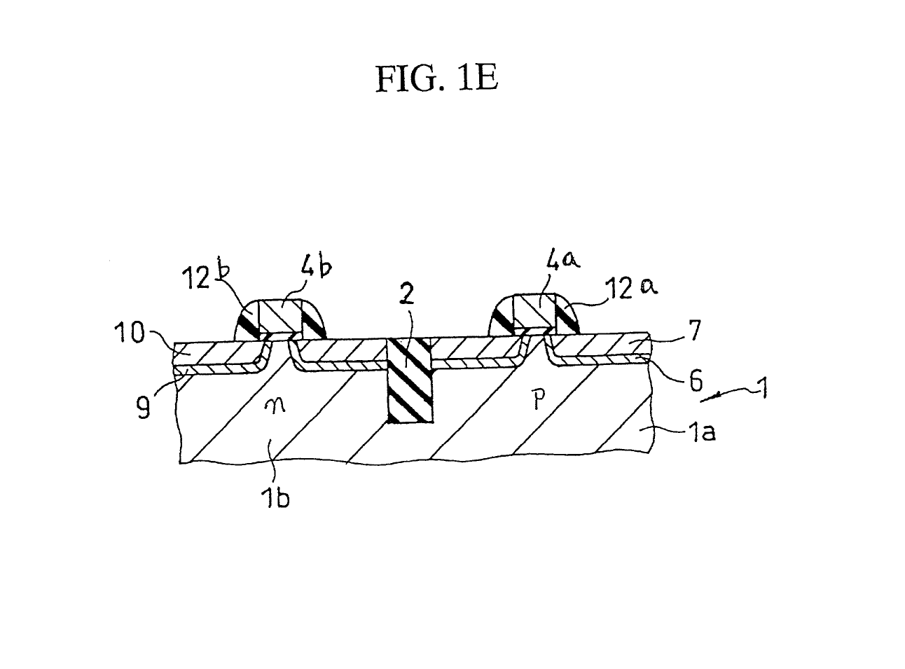

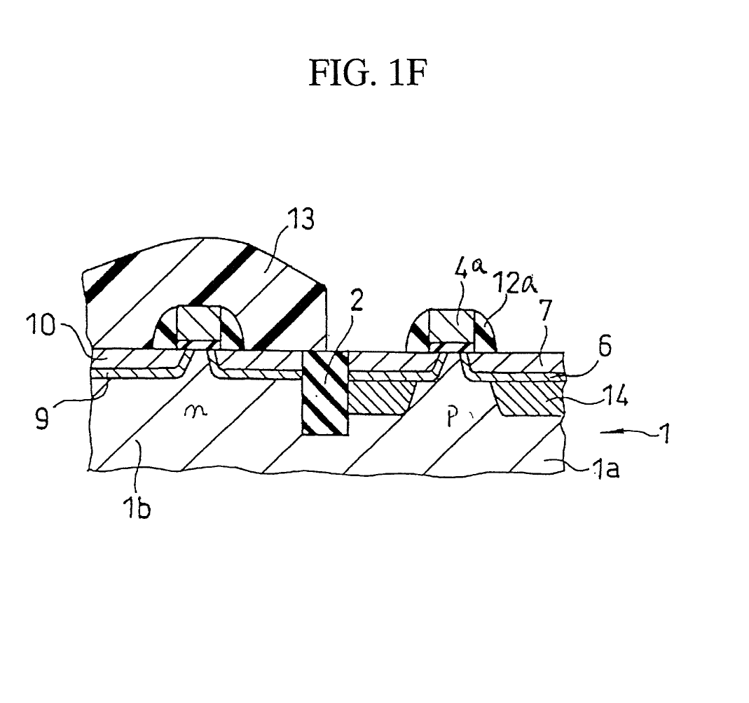

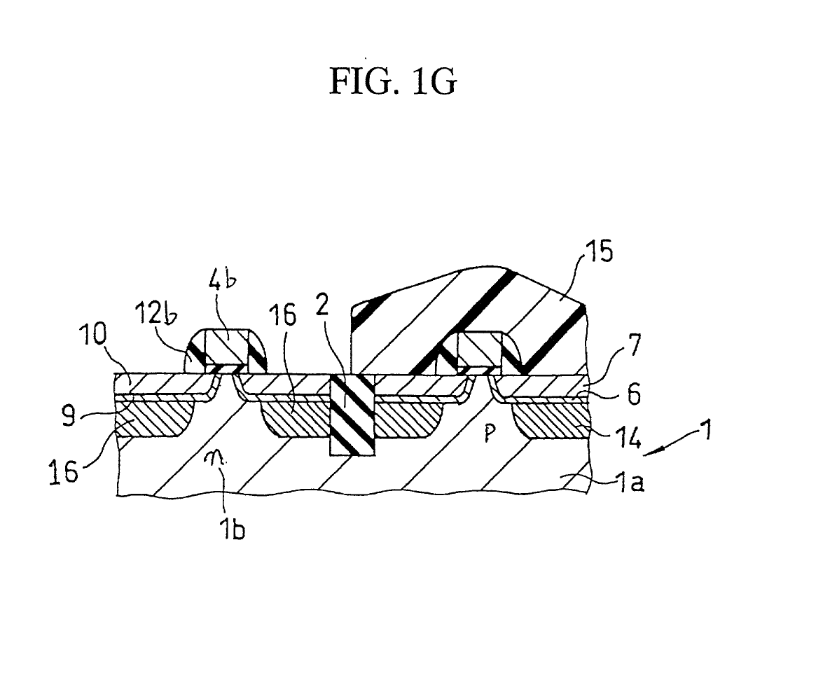

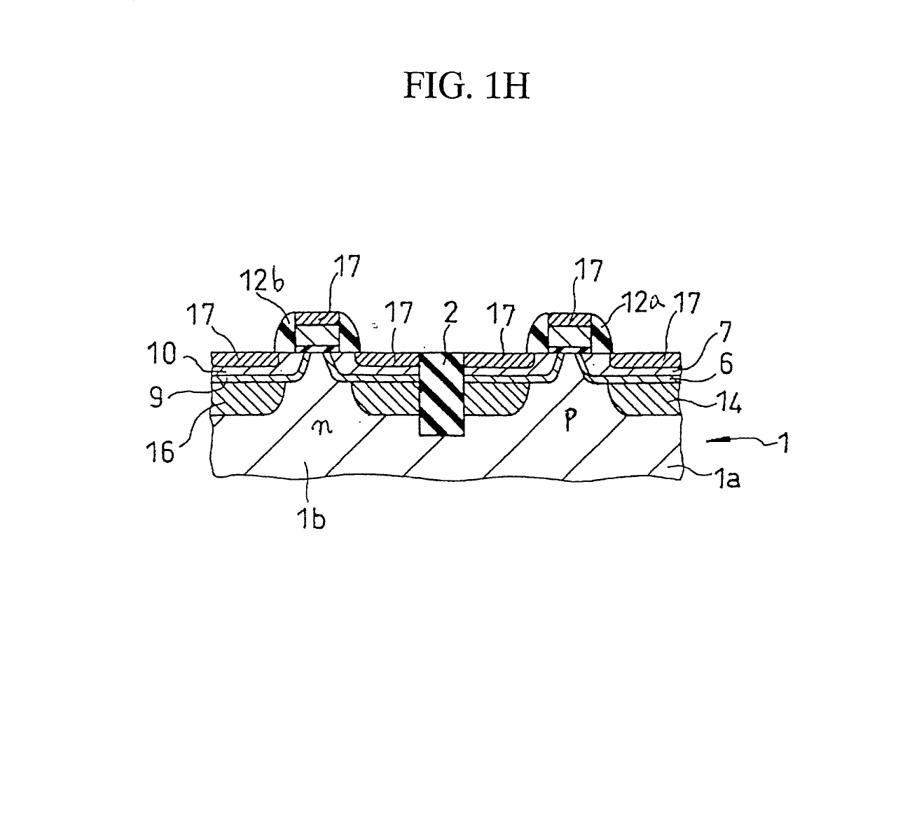

A first embodiment according to the present invention will be described in detail with reference to the drawings. FIGS. 1A through 1H are fragmentary cross sectional elevation views illustrative of semiconductor devices in sequential steps involved in a first novel fabrication method in a first embodiment in accordance with the present invention.

With reference to FIG. 1A, a trench isolation film 2 is selectively formed in a silicon substrate 1 to divide the silicon substrate into first and second regions. An ion-implantation of a p-type impurity into the first region of the silicon substrate 1 is carried out to form a p-well region 1a in the first region of the silicon substrate 1, and further another ion-implantation of an n-type impurity into the second region of the silicon substrate 1 is carried out to form an n-well region 1b in the second region of the silicon substrate 1, wherein the p-well region 1a and the n-well region 1b are separated from each other by the trench isolation film 2. A thermal oxidation is carried out to the surface of the silicon substrate 1 to form a thermal oxidation film having a thickness of 3 nanometers over the surface of the silicon substrate 1. The thermal oxidation film covers both upper surfaces of the p-well region 1a and the n-well region 1b. A chemical vapor deposition film is carried out to form a polysilicon film having a thickness of 150 nanometers on the thermal oxidation film. A resist film is applied on an entire surface of the polysilicon film. A stepper having a krypton fluoride excited dimmer laser as a light source is used to carrier out an exposure to the resist film. Subsequently, a development is carried out to the exposed resist film to pattern the resist film, whereby a resist pattern is formed over the polysilicon film. An anisotropic etching such as a dry etching is carried out to laminations of the polysilicon film and the thermal oxidation film by use of the resist pattern, whereby a first gate electrode 4a and a first gate insulating film 3a are formed over a selected region of the upper surface of the p-well region 1a, and also a second gate electrode 4b and a second gate insulating film 3b are formed over a selected region of the upper surface of the n-well region 1b. The used resist pattern is then removed.

With reference to FIG. 1B, a resist film is entirely applied over the p-well region 1a and the n-well region 1b so that the first and second gate electrodes 4a and 4b are completely buried in the resist film. The resist film is patterned by an exposure process and a subsequent development process to selectively form a resist mask 5 which over only the n-well region 1b and the second gate electrode 4b. An oblique ion-implantation of a p-type impurity such as BF₂ is carried out into the p-well region 1a at an ion-implantation energy of 30 keV, a dose of 1E13 cm⁻², and an oblique angle of 30 degrees by use of the first gate electrode 4a as a mask to form p-type pocket implantation regions 6 in the p-well region 1a. Subsequently, a vertical ion-implantation of an n-type impurity such as As is carried out into the p-well region 1a at an ion-implantation energy of less than 15 keV, a dose of less than 1E15 cm⁻², and an oblique angle of 0 degree by use of the first gate electrode 4a as a mask to form n-type extension regions 7 in the p-type pocket implantation regions 6. The n-type extension regions 7 are shallower than the p-type pocket implantation regions 6.

With reference to FIG. 1C, the used resist mask 5 is removed. Another resist film is then entirely applied over the p-well region 1a and the n-well region 1b so that the first and second gate electrodes 4a and 4b are completely buried in the other resist film. The other resist film is patterned by an exposure process and a subsequent development process to selectively form a resist mask 8 which over only the p-well region 1a and the first gate electrode 4a. An oblique ion-implantation of an n-type impurity such as As is carried out into the n-well region 1b at an ion-implantation energy of less than 15 keV, a dose of less than 1E15 cm⁻², and an oblique angle of 30 degrees by use of the second gate electrode 4b as a mask to form n-type pocket implantation regions 9 in the n-well region 1b. The n-type pocket implantation regions 9 are in the non-amorphous state. Subsequently, a vertical ion-implantation of a p-type impurity such as BF₂ is carried out into the n-well region 1b at an ion-implantation energy of 5 keV, a dose of 5E14 cm⁻², and an oblique angle of 0 degree by use of the second gate electrode 4b as a mask to form p-type extension regions 10 in the n-type pocket implantation regions 9. The p-type extension regions 10 are shallower than the n-type pocket implantation regions 9.

With reference to FIG. 1D, the used resist mask 8 is removed. A chemical vapor deposition process is carried out to entirely deposit an oxide film 11 having a thickness of 100 nanometers over the silicon substrate 1, so that the oxide film 11 covers the first and second gate electrodes 4a and 4b and the upper surfaces of the n-type and p-type extension regions 7 and 10.

With reference to FIG. 1E, an etch-back process is carried out to the oxide film 11, so that the oxide film 11 remain only on side walls of each of the first and second gate electrodes 4a and 4b, whereby first side wall oxide films 12a are formed on the side walls of he first gate electrode 4a and further second side wall oxide films 12b are formed on the side walls of he second gate electrode 4b.

With reference to FIG. 1F, a resist film is entirely applied over the p-well region 1a and the n-well region 1b so that the first and second gate electrodes 4a and 4b with the first and second side wall oxide films 12a and 12b are completely buried in the resist film. The resist film is patterned by an exposure process and a subsequent development process to selectively form a resist mask 13 which over only the n-well region 1b and the second gate electrode 4b. A prior vertical ion-implantation of an n-type impurity such as As is carried out into the p-well region 1a at an ion-implantation energy of less than 15 keV, a dose of less than 1E15 cm⁻², and an oblique angle of 0 degree by use of the first gate electrode 4a with the first side wall oxide film 12a and the resist mask 13 as masks, whereby ion-implanted regions are formed, which overlap the n-type extension regions 7 and also extend to deeper regions of the p-well region 1a than the n-type extension regions 7. The ion-implanted regions are kept in the non-amorphous state, and clusters of As are formed in the ion-implanted non-amorphous regions. A subsequent vertical ion-implantation of another n-type impurity such as P is carried out into the ion-implanted non-amorphous region having the As clusters in the p-well region 1a at an ion-implantation energy of 5 keV, a dose of 1E15 cm², and an oblique angle of 0 degree by use of the first gate electrode 4a with the first side wall oxide film 12a and the resist mask 13 as masks, thereby to form n-type deep source and drain regions 14 in the p-well region 1a. The ion-implanted P forms the other clusters with As in the ion-implanted non-amorphous region. Namely, other clusters of As and P are further formed in the ion-implanted implanted non-amorphous regions. The ion-implanted non-amorphous regions overlap the n-type extension regions 7 and also extend deeper source and drain regions 14. The ion-implanted non-amorphous regions have the clusters of As and the other clusters As and P. This means that surface regions of the n-type extension regions 7 have the clusters of As and the other clusters As and P. The deep source and drain regions 14 have the first type clusters of As and the second type clusters of As and P. Namely, the clusters of As are formed in the ion-implanted non-amorphous regions overlapping the n-type extension regions 7 and also extending deeper regions by the prior ion-implantation process. Subsequently, when P is ion-implanted into the ion-implanted non-amorphous regions with the As clusters by the subsequent ion-implantation process, then P forms other clusters with As. Thus, the other clusters of As and P are formed in the ion-implanted non-amorphous regions overlapping the n-type extension regions 7 and also extending the deeper source and drain regions 14. Accordingly, the ion-implanted non-amorphous regions overlapping the n-type extension regions 7 and also extending the deeper source and drain regions 14 have the clusters of As and the other clusters of As and P. Namely, surface regions of the n-type extension regions 7 have the clusters of As and the other clusters As and P.

The n-type deep source and drain regions 14 are deeper than the p-type pocket implantation regions 6 and also deeper than the n-type extension regions 7. Inside edges of the n-type deep source and drain regions 14 are self-aligned to the first side wall oxide film 12a. The inside edges of the n-type deep source and drain regions 14 are positioned more inside of the inside edges of the p-type pocket implantation regions 6 and also the n-type extension regions 7.

With reference to FIG. 1G, the used resist mask 13 is then removed. Another resist film is entirely applied over the p-well region 1aand the n-well region 1b so that the first and second gate electrodes 4a and 4b with the first and second side wall oxide films 12a and 12b are completely buried in the other resist film. The other resist film is patterned by an exposure process and a subsequent development process to selectively form another resist mask 15 which over only the p-well region la and the first gate electrode 4a. A vertical ion-implantation of a p-type impurity such as B is carried out into the n-well region 1b at an ion-implantation energy of 3 keV, a dose of 5E15 cm⁻², and an oblique angle of 0 degree by use of the second gate electrode 4b with the second side wall oxide film 12b and the resist mask 15 as masks, thereby to form p-type deep source and drain regions 16 in the n-well region 1b. The p-type deep source and drain regions 16 are deeper than the n-type pocket implantation regions 9 and also deeper than the p-type extension regions 10. Inside edges of the p-type deep source and drain regions 16 are self-aligned to the second side wall oxide film 12b. The inside edges of the p-type deep source and drain regions 16 are positioned more inside of the inside edges of the n-type pocket implantation regions 9 and also the p-type extension regions 10. The used resist mask 15 is then removed.

Subsequently, a rapid thermal annealing process is carried out in an oxygen atmosphere having an oxygen concentration of 1 percent by volume at a temperature of 1000° C. for 10 seconds to activate the impurities in the first and second gate electrodes 4a and 4b, the n-type extension regions 7, the p-type extension regions 10, the n-type deep source and drain regions 14 and the p-type deep source and drain regions 16, whereby the n-type extension regions 7, the p-type extension regions 10, the n-type deep source and drain regions 14 and the p-type deep source and drain regions 16 become impurity diffusion regions. Namely, the n-type extension diffusion regions 7, the p-type extension diffusion regions 10, the n-type deep source and drain diffusion regions 14 and the p-type deep source and drain diffusion regions 16 are formed. The rapid thermal annealing process causes the impurity diffusion. As described above, the ion-implanted non-amorphous regions overlapping the n-type extension regions 7 and also extending the deeper source and drain regions 14 have the clusters of As and the other clusters of As and P. Namely, surface regions of the n-type extension regions 7 have the clusters of As and the other clusters As and P. Both the clusters of As and the other clusters As and P serve to effectively suppress the outward diffusion of P, for example, the diffusion of P from the upper surfaces of the n-type extension regions 7. This suppression to the outward diffusion of P allows formation of the shallow junction diffusion regions. Further, the above-described rapid thermal annealing process for activation of the impurities in the diffusion regions causes enhanced oxidations of P and/or B, whereby surface oxide films over the upper surfaces of the n-type extension regions 7 and the p-type type extension regions 10 are increased in thickness or amount. The surface oxide films over the upper surface of the n-type extension regions 7 suppress the outward diffusion of P, for example, the diffusion of P from the upper surfaces of the n-type extension regions 7 even if the oxygen concentration of the atmosphere for the rapid thermal annealing. This suppression to the outward diffusion of P by the surface oxide films allows keeping a low sheet resistance of the diffusion regions. This allows that not only the diffusion regions in the n-well region 1b but also the diffusion regions in the p-well region 1a have the reduced sheet resistance and the shallow junction.

With reference to FIG. 1H, a refractory metal film such as a cobalt film having a thickness of 10 nanometers is entirely deposited over the substrate 1 by a sputtering method, so that the cobalt film extends over the surfaces of the n-type extension regions 7 and the p-type extension regions 10 as well as over the first and second gate electrodes 4a and 4b with the first and second side wall oxide films 12a and 12b. A rapid thermal annealing process is carried out in a pure nitrogen atmosphere having a nitrogen concentration of 100 percents by volume, at a temperature of 700° C. for 30 seconds to cause a silicidation reaction between cobalt and silicon. A further rapid thermal annealing process is carried out in the pure nitrogen atmosphere having a nitrogen concentration of 100 percents by volume, at a temperature of 750° C. for 30 seconds to form cobalt silicide films 17 on the upper surfaces of the first and second gate electrodes 4a and 4b and on the upper surfaces of the n-type extension regions 7 and the p-type extension regions 10. The excess and unreacted cobalt films are removed by an isotropic etching process such as a wet etching process. In place of cobalt, other refractory metal films may be available, for example, a titanium film. In this case, the titanium silicide films are formed in place of the cobalt silicide films. Subsequently, an inter-layer insulator not illustrated is entirely formed over the substrate 1, and contact holes are formed in the inter-layer insulator. Interconnections are formed over the inter-layer insulator, wherein the interconnections are electrically connected through contact plugs in the contact holes to the p-channel and n-channel MOS field effect transistors.

In accordance with the first novel method, the prior vertical ion-implantation of an n-type impurity such as As is carried out, whereby ion-implanted regions are formed, which overlap the n-type extension regions 7 and also extend to deeper regions of the p-well region 1a than the n-type extension regions 7. The ion-implanted regions are kept in the non-amorphous state, and clusters of As are formed in the ion-implanted non-amorphous regions. A subsequent vertical ion-implantation of another n-type impurity such as P is carried out into the ion-implanted non-amorphous region having the As clusters in the p-well region 1a, thereby to form n-type deep source and drain regions 14 in the p-well region 1a. The ion-implanted P forms the other clusters with As in the ion-implanted non-amorphous region. Namely, other clusters of As and P are further formed in the ion-implanted non-amorphous regions. The ion-implanted non-amorphous regions overlap the n-type extension regions 7 and also extend deeper source and drain regions 14. The ion-implanted non-amorphous regions have the clusters of As and the other clusters As and P. This means that surface regions of the n-type extension regions 7 have the clusters of As and the other clusters As and P. The clusters of As are formed in the ion-implanted non-amorphous regions overlapping the n-type extension regions 7 and also extending deeper regions by the prior ion-implantation process. Subsequently, when P is ion-implanted into the ion-implanted non-amorphous regions with the As clusters by the subsequent ion-implantation process, then P forms other clusters with As. Thus, the other clusters of As and P are formed in the ion-implanted non-amorphous regions overlapping the n-type extension regions 7 and also extending the deeper source and drain regions 14. Accordingly, the ion-implanted non-amorphous regions overlapping the n-type extension regions 7 and also extending the deeper source and drain regions 14 have the clusters of As and the other clusters of As and P. Namely, surface regions of the n-type extension regions 7 have the clusters of As and the other clusters As and P. Subsequently, the heat treatment such as the rapid thermal annealing process is carried out to activate the impurities. As described above, the ion-implanted non-amorphous regions overlapping the n-type extension regions 7 and also extending the deeper source and drain regions 14 have the clusters of As and the other clusters of As and P. Namely, surface regions of the n-type extension regions 7 have the clusters of As and the other clusters As and P. Both the clusters of As and the other clusters As and P serve to effectively suppress the outward diffusion of P, for example, the diffusion of P from the upper surfaces of the n-type extension regions 7. This suppression to the outward diffusion of P allows formation of the shallow junction diffusion regions. Further, the above-described rapid thermal annealing process for activation of the impurities in the diffusion regions causes enhanced oxidations of P and/or B, whereby surface oxide films over the upper surfaces of the n-type extension regions 7 and the p-type extension regions 10 are increased in thickness or amount. The surface oxide films over the upper surface of the n-type extension regions 7 suppress the outward diffusion of P, for example, the diffusion of P from the upper surfaces of the n-type extension regions 7 even if the oxygen concentration of the atmosphere for the rapid thermal annealing. This suppression to the outward diffusion of P by the surface oxide films allows keeping a low sheet resistance of the diffusion regions. This allows that not only the diffusion regions in the n-well region 1b but also the diffusion regions in the p-well region 1a have the reduced sheet resistance and the shallow junction.

In the above embodiment, As is implanted before P is then implanted. As a modification, it is possible that P is implanted before As is then implanted. In view of a possible reduction in mount or number of the crystal defects caused by the impurity implantation, it is preferable that As is implanted before P is then implanted in the above embodiment. The above implantation energies and the doses for the prior and subsequent ion-implantations for implanting As and P may be varied in accordance with the device rules, provided that the As-implanted regions are in the non-amorphous amorphous state to form the As-clusters and hen allow the later formation of other clusters of As and P upon later implantation of P. In the above embodiment, As is selected as the impurity which suppress the outward diffusion of P. In place of As, Ge and Ar are also available as the impurity which suppress the outward diffusion of P. Of course, two or three combinations of As, Ge and Ar may also be implanted as the impurities which suppress the outward diffusion of P.

In the above embodiment, As is implanted to form the n-type extension regions 7. As a further modification, it is possible that P, As₂, P₂, and combinations thereof are implanted to form the n-type extension regions 7. In the above embodiment, BF2 is implanted to form the p-type extension regions 10. As a further modification, it is possible that B is implanted to form the p-type extension regions 10. In the above embodiment, B is implanted to form the deep p-type source and drain regions 16. As a further modification, it is possible that BF₂ is implanted to form the deep p-type source and drain regions 16. In the above embodiment, the side wall insulating films 12 comprise the single oxide film formed by the chemical vapor deposition method. As a further modification, it is possible that the side wall insulating films 12 comprise double layered structure or tripe layered structure of the oxide film and nitride film.

In the above embodiment, the substrate 1 is the silicon substrate 1. As a modification, it is possible that the substrate 1 comprises a silicon-on-insulator substrate or an epitaxial substrate. In the above embodiment, the gate insulating films 3a and 3b comprise the oxide films. As a modification, it is possible that the gate insulating films 3a and 3b comprise oxy-nitride films.

In accordance with the first novel method, it is unnecessary to form the cover film on the upper surface of the p-well region 1a for carrying out the heat treatment in the same oxygen atmosphere having the same oxygen concentration, because the As clusters and the As—P clusters suppress or prevent the outward diffusion of P. As a result, it is possible to form the shallow diffusion regions with the reduced sheet resistance even no cover film is selectively formed over the p-well region 1a. The oxygen concentration of the atmosphere, in which the heat treatment is carried out to activate the impurities, may preferably be in the range of 0.05 percents by volume to 1 percent by volume, wherein the surface oxide films are naturally formed over the upper surfaces of the diffusion regions, and the surface oxide films further contribute to suppress the outward diffusion of P. If the oxygen concentration of the atmosphere is lower than the above preferable range, then it might be possible that the suppression to the outward diffusion of P is imperfect, and the reduction in the sheet resistance of the diffusion regions is insufficient. If, however, the oxygen concentration of the atmosphere is higher than the above preferable range, then the oxygen enhanced diffusion of B or P is caused, thereby making it difficult to form the shallow junction. In the above embodiment, the cobalt silicide films are formed. As a modification, it is possible that other refractory metal silicide layers such as titanium silicide layers are formed.

Second Embodiment:

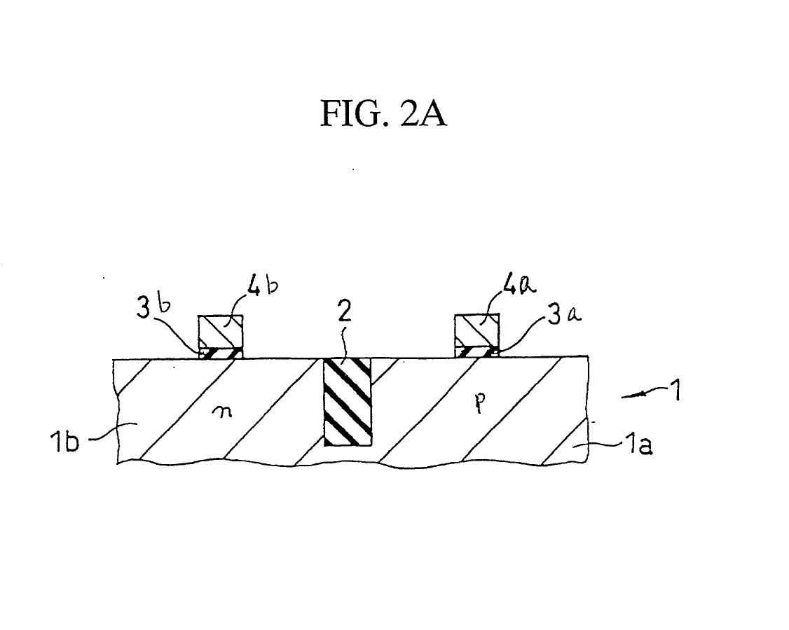

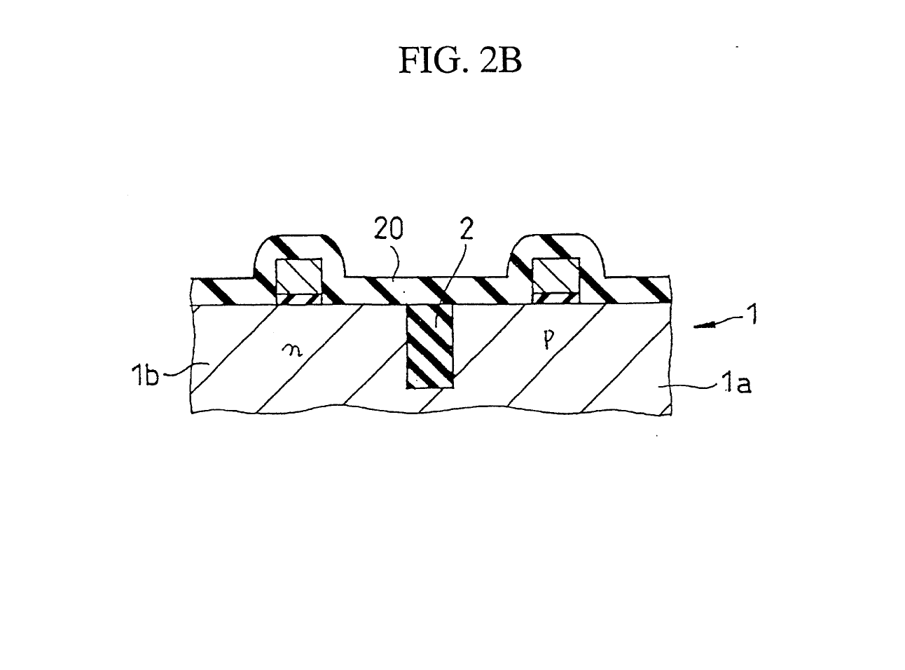

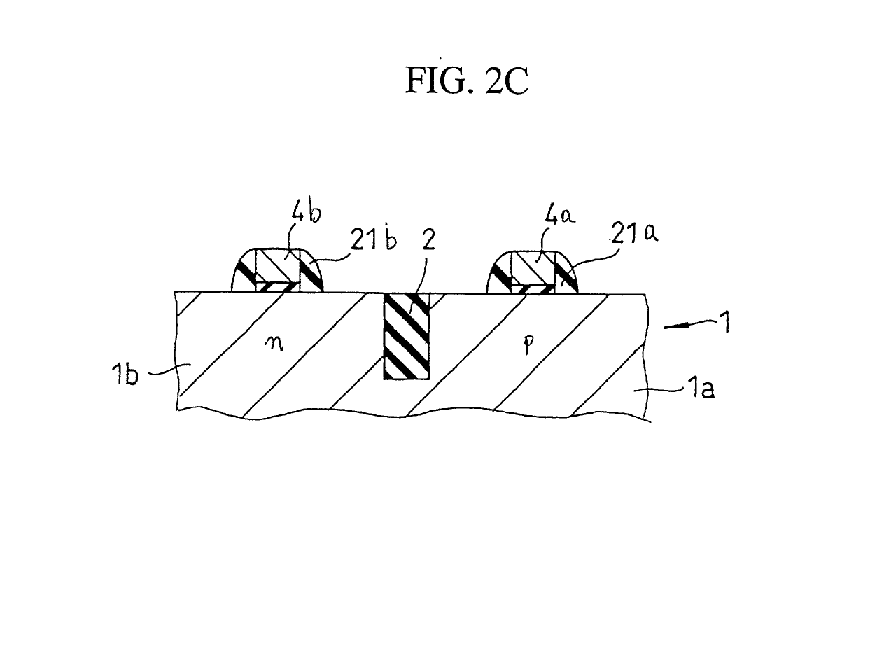

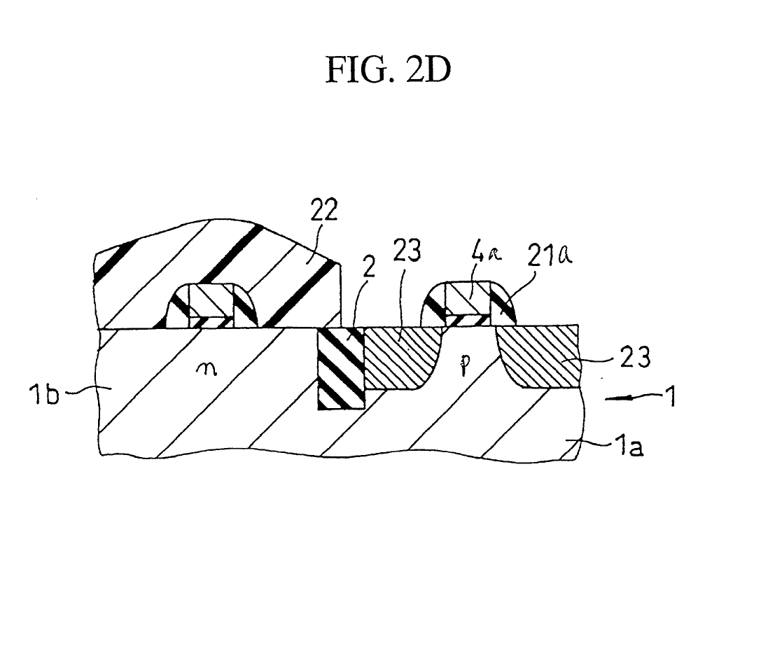

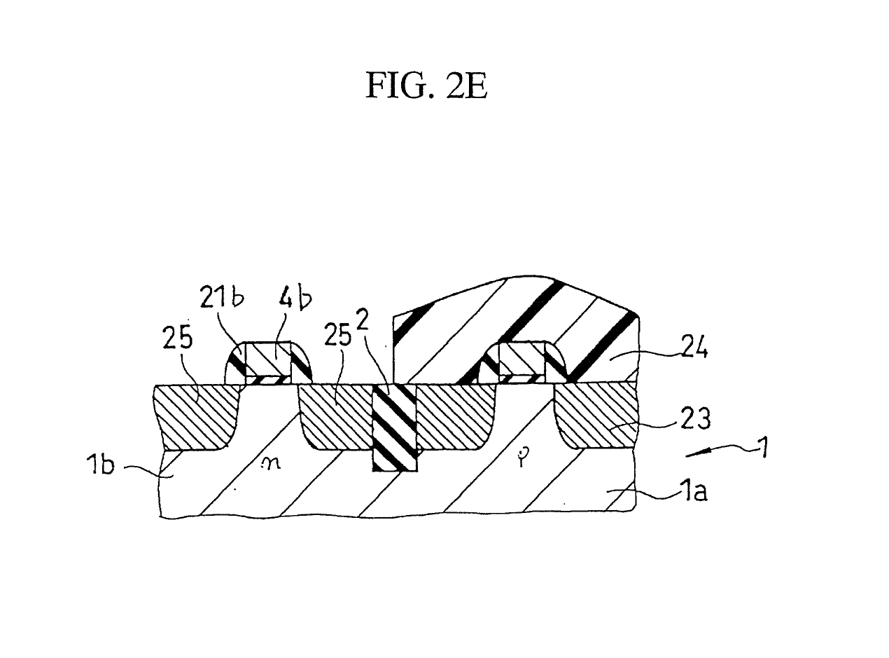

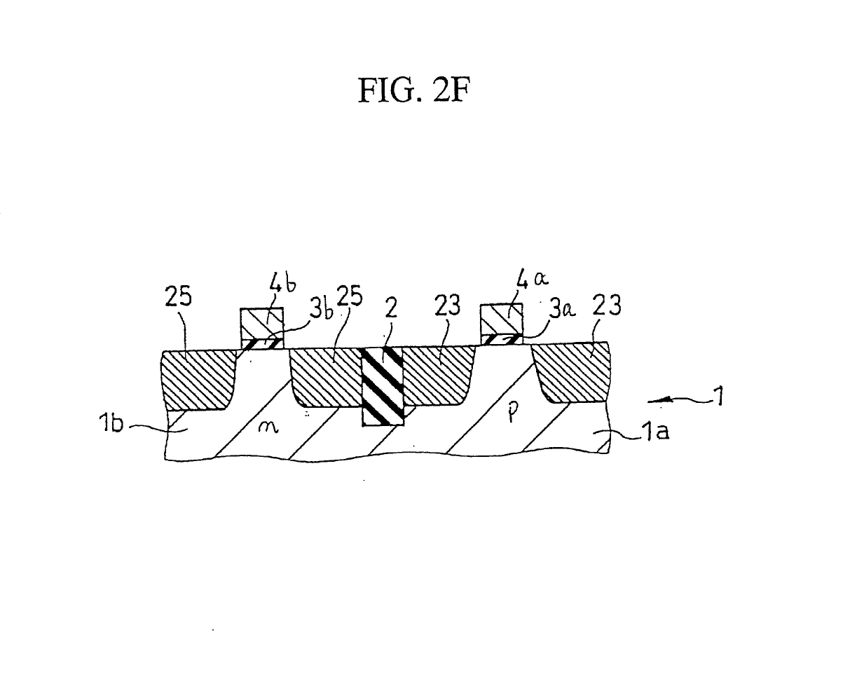

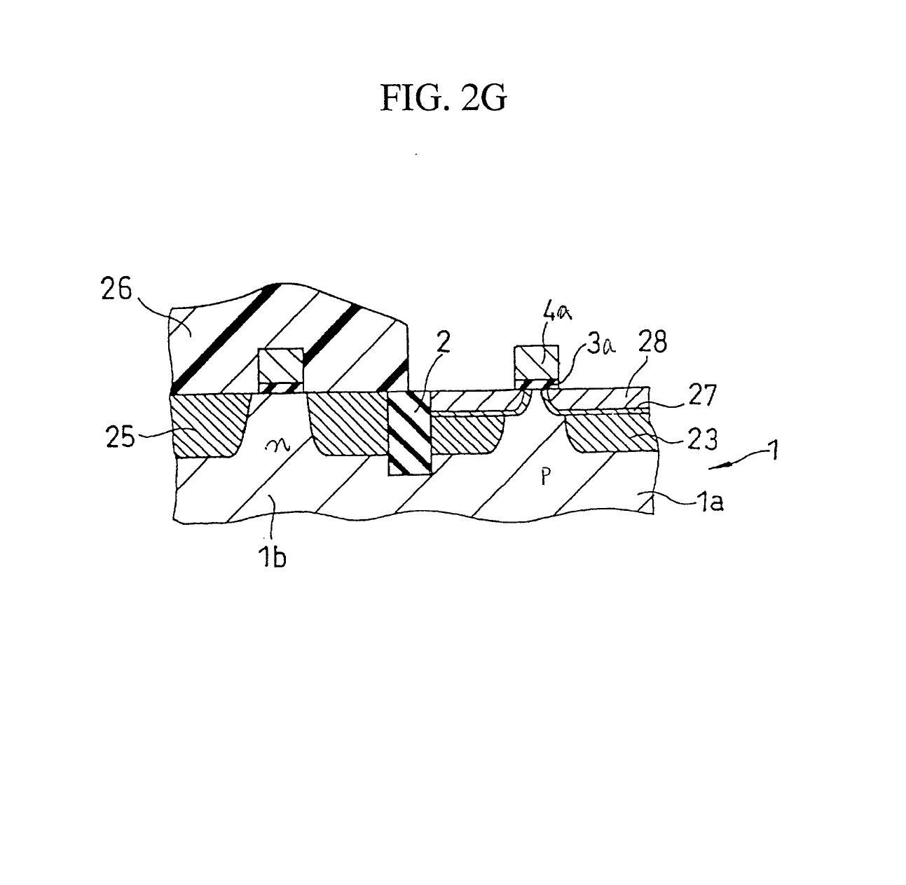

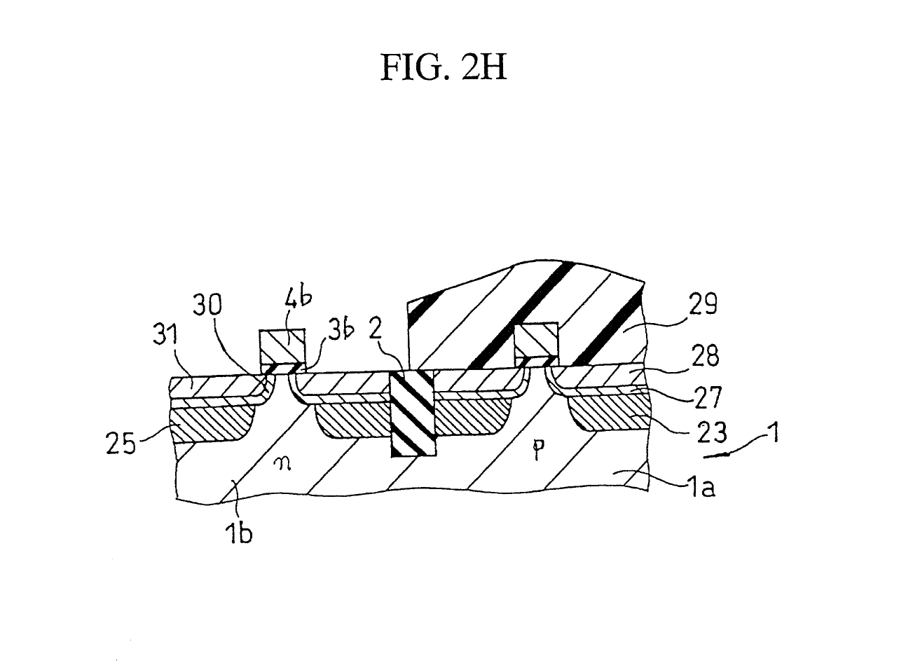

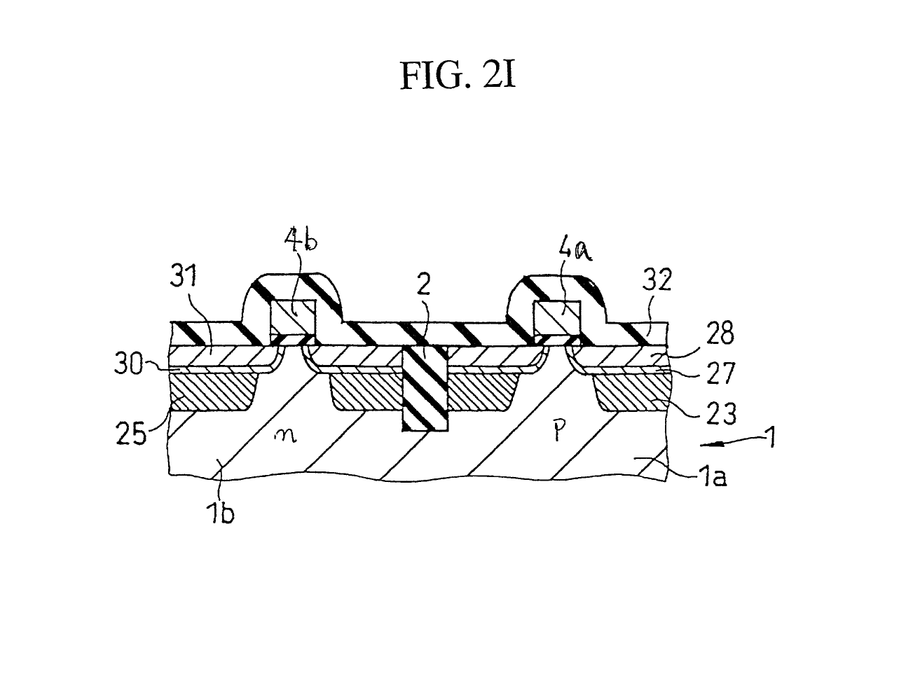

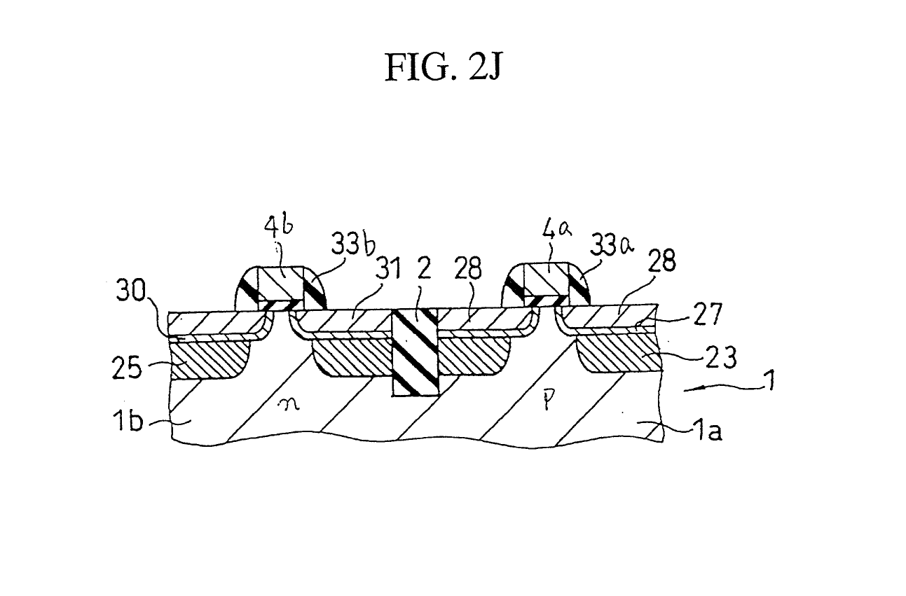

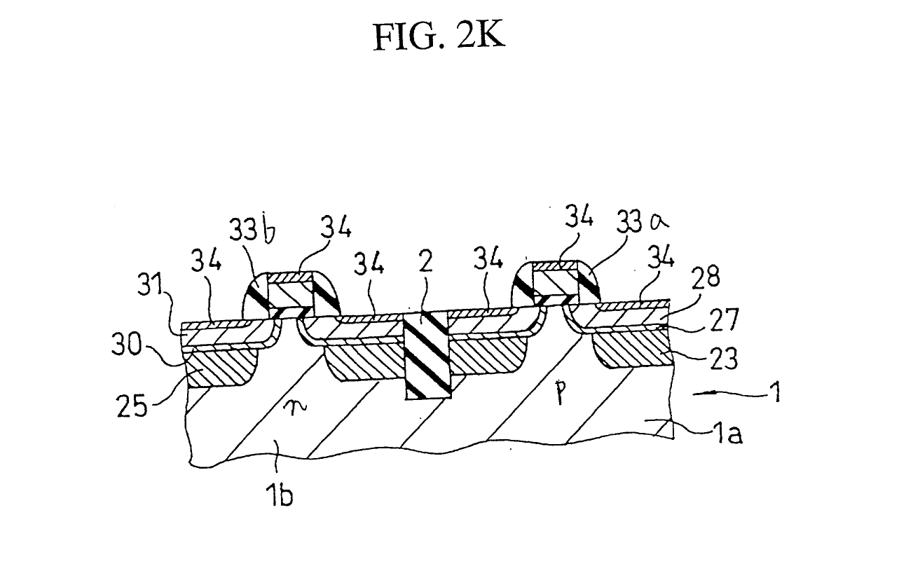

A second embodiment according to the present invention will be described in detail with reference to the drawings. FIGS. 2A through 2K are fragmentary cross sectional elevation views illustrative of semiconductor devices in sequential steps involved in a second novel fabrication method in a second embodiment in accordance with the present invention.

With reference to FIG. 2A, a trench isolation film 2 is selectively formed in a silicon substrate 1 to divide the silicon substrate into first and second regions. An ion-implantation of a p-type impurity into the first region of the silicon substrate 1 is carried out to form a p-well region 1a in the first region of the silicon substrate 1, and further another ion-implantation of an n-type impurity into the second region of the silicon substrate 1 is carried out to form an n-well region 1b in the second region of the silicon substrate 1, wherein the p-well region 1a and the n-well region 1b are separated from each other by the trench isolation film 2. A thermal oxidation is carried out to the surface of the silicon substrate 1 to form a thermal oxidation film having a thickness of 3 nanometers over the surface of the silicon substrate 1. The thermal oxidation film covers both upper surfaces of the p-well region 1a and the n-well region 1b. A chemical vapor deposition film is carried out to form a polysilicon film having a thickness of 150 nanometers on the thermal oxidation film. A resist film is applied on an entire surface of the polysilicon film. A stepper having a krypton fluoride excited dimmer laser as a light source is used to carrier out an exposure to the resist film. Subsequently, a development is carried out to the exposed resist film to pattern the resist film, whereby a resist pattern is formed over the polysilicon film. An anisotropic etching such as a dry etching is carried out to laminations of the polysilicon film and the thermal oxidation film by use of the resist pattern, whereby a first gate electrode 4a and a first gate insulating film 3a are formed over a selected region of the upper surface of the p-well region 1a, and also a second gate electrode 4b and a second gate insulating film 3b are formed over a selected region of the upper surface of the n-well region 1b. The used resist pattern is then removed.

With reference to FIG. 2B, a chemical vapor deposition method is carried out to form an oxide film 20 entirely over the substrate 1, so that the oxide film 20 extends over the upper surfaces of the p-well region 1a and the n-well region 1b and also the first and second gate electrodes 4a and 4b. The oxide film 20 may have a thickness of 100 nanometers.

With reference to FIG. 2C, an etch-back process to the oxide film 20 is carried out to have the oxide film 20 remain only on the side walls of each of the first and second gate electrodes 4a and 4b, whereby first side wall oxide films 21a are formed on the side walls of the first gate electrode 4a and second side wall oxide films 21b are formed on the side walls of the second gate electrode 4b.

With reference to FIG. 2D, a resist film is entirely applied over the p-well region 1a and the n-well region 1b so that the first and second gate electrodes 4a and 4b with the first and second side wall oxide films 21a and 21b are completely buried in the resist film. The resist film is patterned by an exposure process and a subsequent development process to selectively form a resist mask 22 which over only the n-well region 1b and the second gate electrode 4b. A prior vertical ion-implantation of an n-type impurity such as As is carried out into the p-well region 1a at an ion-implantation energy of less than 15 keV, a dose of less than 1E15 cm⁻², and an oblique angle of 0 degree by use of the first gate electrode 4a with the first side wall oxide film 21a and the resist mask 22 as masks, whereby ion-implanted regions are formed, which extend from the upper surface region of the p-well region 1a to the deeper region of the p-well region 1a. The ion-implanted regions are kept in the non-amorphous state, and clusters of As are formed in the ion-implanted non-amorphous regions. A subsequent vertical ion-implantation of another n-type impurity such as P is carried out into the ion-implanted non-amorphous region having the As clusters in the p-well region 1a at an ion-implantation energy of 5 keV, a dose of 1E15 cm⁻², and an oblique angle of 0 degree by use of the first gate electrode 4a with the first side wall oxide film 21a and the resist mask 22 as masks, thereby to form n-type deep source and drain regions 23 in the p-well region 1a, wherein the n-type deep source and drain regions 23 extend from the upper surface region of the p-well region 1a to the deeper region of the p-well region 1a. Namely, other clusters of As and P are further formed in the ion-implanted non-amorphous regions or the n-type deep source and drain regions 23 extending from the upper surface region of the p-well region 1a to the deeper region of the p-well region 1a. The ion-implanted non-amorphous regions have the clusters of As and the other clusters As and P. This means that surface regions of the n-type deep source and drain regions 23 have the clusters of As and the other clusters As and P. The deep source and drain regions 23 have the first type clusters of As and the second type clusters of As and P. Namely, the clusters of As are formed in the ion-implanted non-amorphous regions or the n-type deep source and drain regions 23 extending from the upper surface region of the p-well region 1a to the deeper region of the p-well region 1a by the prior ion-implantation process. Subsequently, when P is ion-implanted into the ion-implanted non-amorphous regions with the As clusters by the subsequent ion-implantation process, then P forms other clusters with As. Thus, the other clusters of As and P are formed in the ion-implanted regions or the n-type deep source and drain regions 23 extending from the upper surface region of the p-well region 1a to the deeper region of the p-well region 1a. Accordingly, the ion-implanted regions have the clusters of As and the other clusters of As and P. Namely, surface regions of the p-well region 1a have the clusters of As and the other clusters As and P.

With reference to FIG. 2E, the used resist mask 22 is then removed. Another resist film is entirely applied over the p-well region 1a and the n-well region 1b so that the first and second gate electrodes 4a and 4b with the first and second side wall oxide films 21a and 21b are completely buried in the other resist film. The other resist film is patterned by an exposure process and a subsequent development process to selectively form another resist mask 24 which over only the p-well region 1a and the first gate electrode 4a. A vertical ion-implantation of a p-type impurity such as B is carried out into the n-well region 1b at an ion-implantation energy of 3 keV, a dose of 5E15 cm⁻², and an oblique angle of 0 degree by use of the second gate electrode 4b with the second side wall oxide film 21b and the resist mask 24 as masks, thereby to form p-type deep source and drain regions 25 in the n-well region 1b. Inside edges of the p-type deep source and drain regions 25 are self-aligned to the second side wall oxide film 21b. The p-type deep source and drain regions 25 extend from the upper surface region of the n-well region 1b to the deeper region of the n-well region 1b.

With reference to FIG. 2F, the used resist mask 24 is removed. A rapid thermal annealing process is carried out in an oxygen atmosphere having an oxygen concentration of 1 percent by volume at a temperature of 1000° C. for 10 seconds to activate the impurities in the first and second gate electrodes 4a and 4b, the n-type deep source and drain regions 23 and the p-type deep source and drain regions 25, whereby the n-type deep source and drain regions 23 and the p-type deep source and drain regions 25 become impurity diffusion regions. Namely, the n-type deep source and drain diffusion regions 23 and the p-type deep source and drain diffusion regions 25 are formed. The rapid thermal annealing process causes the impurity diffusion. As described above, the ion-implanted deeper source and drain regions 23 have the clusters of As and the other clusters of As and P. Namely, surface regions of the ion-implanted deeper source and drain regions 23 have the clusters of As and the other clusters As and P. Both the clusters of As and the other clusters As and P serve to effectively suppress the outward diffusion of P, for example, the diffusion of P from the upper surfaces of the ion-implanted deeper source and drain regions 23. This suppression to the outward diffusion of P allows formation of the shallow junction diffusion regions. Further, the above-described rapid thermal annealing process for activation of the impurities in the diffusion regions causes enhanced oxidations of P and/or B, whereby surface oxide films over the upper surfaces of the ion-implanted deeper source and drain regions 23 and the ion-implanted deeper source and drain regions 25 are increased in thickness or amount. The surface oxide films over the upper surface of the ion-implanted deeper source and drain regions 23 suppress the outward diffusion of P, for example, the diffusion of P from the upper surfaces of the ion-implanted deeper source and drain regions 23 even if the oxygen concentration of the atmosphere for the rapid thermal annealing. This suppression to the outward diffusion of P by the surface oxide films allows keeping a low sheet resistance of the diffusion regions. This allows that not only the diffusion regions in the n-well region 1b but also the diffusion regions in the p-well region 1a have the reduced sheet resistance and the shallow junction. The first and second side wall oxide films 21a and 21b are removed by an isotropic etching such as a wet etching.

With reference to FIG. 2G, a resist film is entirely applied over the p-well region 1a and the n-well region 1b so that the first and second gate electrodes 4a and 4b are completely buried in the resist film. The resist film is patterned by an exposure process and a subsequent development process to selectively form a resist mask 26 which over only the n-well region 1b and the second gate electrode 4b. An oblique ion-implantation of a p-type impurity such as BF2 is carried out into the p-well region 1a at an ion-implantation energy of 30 keV, a dose of 1E13 cm⁻², and an oblique angle of 30 degrees by use of the first gate electrode 4a and the resist mask 26 as masks to form p-type pocket implantation regions 27 in the p-well region 1a. The p-type pocket implantation regions 27 overlap upper regions of the deep source and drain diffusion regions 23. The p-type pocket implantation regions 27 are shallower than the deep source and drain diffusion regions 23. Subsequently, a prior vertical ion-implantation of an n-type impurity such as As is carried out into the p-well region 1a at an ion-implantation energy of less than 5 keV, a dose of less than 1E15 cm⁻², and an oblique angle of 0 degree by use of the first gate electrode 4a as a mask. The As-implanted regions are in the non-amorphous state, and have As-clusters. Further, a subsequent vertical ion-implantation of another n-type impurity such as P is carried out into the As-implanted non-amorphous regions with the As-clusters in the p-well region 1a at an ion-implantation energy of less than 1 keV, a dose of less than 2E14 cm⁻², and an oblique angle of 0 degree by use of the first gate electrode 4b as a mask to form n-type extension regions 28 in the p-type pocket implantation regions 27. The n-type extension regions 28 are shallower than the p-type pocket implantation regions 27. Other clusters of As and P are further formed in the n-type extension regions 28. The n-type extension regions 28 have the clusters of As and the other clusters As and P. This means that surface regions of the n-type extension regions 28 have the clusters of As and the other clusters As and P. The n-type extension regions 28 have the first type clusters of As and the second type clusters of As and P. Namely, the clusters of As are formed in the ion-implanted non-amorphous regions by the prior ion-implantation process. Subsequently, when P is ion-implanted into the ion-implanted non-amorphous regions with the As clusters by the subsequent ion-implantation process, then P forms other clusters with As. Thus, the other clusters of As and P are formed in the ion-implanted regions or the n-type extension regions 28. Accordingly, the n-type extension regions 28 have the clusters of As and the other clusters of As and P. Namely, surface regions of the p-well region 1a have the clusters of As and the other clusters As and P.

With reference to FIG. 2H, the used resist mask 26 is removed. Another resist film is then entirely applied over the p-well region 1a and the n-well region 1b so that the first and second gate electrodes 4a and 4b are completely buried in the other resist film. The other resist film is patterned by an exposure process and a subsequent development process to selectively form a resist mask 29 which over only the p-well region 1a and the first gate electrode 4a. An oblique ion-implantation of an n-type impurity such as As is carried out into the n-well region 1b at an ion-implantation energy of less than 15 keV, a dose of less than 1E15 cm⁻², and an oblique angle of 30 degrees by use of the second gate electrode 4b as a mask to form n-type pocket implantation regions 30 in the n-well region 1b. The n-type pocket implantation regions 30 are in the non-amorphous state. Subsequently, a vertical ion-implantation of a p-type impurity such as BF₂ is carried out into the n-well region 1b at an ion-implantation energy of less than 5 keV, a dose of 5E14 cm⁻², and an oblique angle of 0 degree by use of the second gate electrode 4b as a mask to form p-type extension regions 31 in the n-type pocket implantation regions 30. The p-type extension regions 31 are shallower than the n-type pocket implantation regions 30.

With reference to FIG. 2I, the used resist mask 29 is removed. A rapid thermal annealing process is carried out in an oxygen atmosphere having an oxygen concentration of 1 percent by volume at a temperature of 1000° C. for 3 seconds to activate the impurities in the n-type extension regions 28 and the p-type extension regions 31, whereby the n-type extension regions 28 and the p-type extension regions 31 become impurity diffusion regions. Namely, the n-type extension diffusion regions 28 and the p-type extension diffusion regions 31 are formed. The rapid thermal annealing process causes the impurity diffusion. As described above, the n-type extension regions 28 have the clusters of As and the other clusters of As and P. Namely, surface regions of the ion-implanted n-type extension regions 28 have the clusters of As and the other clusters As and P. Both the clusters of As and the other clusters As and P serve to effectively suppress the outward diffusion of P, for example, the diffusion of P from the upper surfaces of the ion-implanted n-type extension regions 28. This suppression to the outward diffusion of P allows formation of the shallow junction diffusion regions. Further, the above-described rapid thermal annealing process for activation of the impurities in the diffusion regions causes enhanced oxidations of P and/or B, whereby surface oxide films over the upper surfaces of the ion-implanted n-type extension regions 28 and p-type extension regions 31 are increased in thickness or amount. The surface oxide films over the upper surface of the ion-implanted n-type extension regions 28 suppress the outward diffusion of P, for example, the diffusion of P from the upper surfaces of the ion-implanted n-type extension regions 28 even if the oxygen concentration of the atmosphere for the rapid thermal annealing. This suppression to the outward diffusion of P by the surface oxide films allows keeping a low sheet resistance of the diffusion regions. This allows that not only the diffusion regions in the n-well region 1b but also the diffusion regions in the p-well region 1a have the reduced sheet resistance and the shallow junction. A chemical vapor deposition process is carried out to entirely deposit an oxide film 32 having a thickness of 100 nanometers over the silicon substrate 1, so that the oxide film 32 covers the first and second gate electrodes 4a and 4b and the upper surfaces of the n-type and p-type extension regions 28 and 31.

With reference to FIG. 2J, an etch-back process is carried out to the oxide film 32, so that the oxide film 32 remain only on side walls of each of the first and second gate electrodes 4a and 4b, whereby first side wall oxide films 33a are formed on the side walls of he first gate electrode 4a and further second side wall oxide films 33b are formed on the side walls of he second gate electrode 4b.

With reference to FIG. 2K, a refractory metal film such as a cobalt film having a thickness of 10 nanometers is entirely deposited over the substrate 1 by a sputtering method, so that the cobalt film extends over the surfaces of the n-type extension regions 28 and the p-type extension regions 31 as well as over the first and second gate electrodes 4a and 4b with the first and second side wall oxide films 33a and 33b. A rapid thermal annealing process is carried out in a pure nitrogen atmosphere having a nitrogen concentration of 100 percents by volume, at a temperature of 700° C. for 30 seconds to cause a silicidation reaction between cobalt and silicon. A further rapid thermal annealing process is carried out in the pure nitrogen atmosphere having a nitrogen concentration of 100 percents by volume, at a temperature of 750° C. for 30 seconds to form cobalt silicide films 34 on the upper surfaces of the first and second gate electrodes 4a and 4b and on the upper surfaces of the n-type extension regions 28 and the p-type extension regions 31. The excess and unreacted cobalt films are removed by an isotropic etching process such as a wet etching process. In place of cobalt, other refractory metal films may be available, for example, a titanium film. In this case, the titanium silicide films are formed in place of the cobalt silicide films. Subsequently, an inter-layer insulator not illustrated is entirely formed over the substrate 1, and contact holes are formed in the inter-layer insulator. Interconnections are formed over the inter-layer insulator, wherein the interconnections are electrically connected through contact plugs in the contact holes to the p-channel and n-channel MOS field effect transistors.

In accordance with the second novel method, the prior vertical ion-implantation of an n-type impurity such as As is carried out, whereby ion-implanted regions are formed, which extend from the upper surface of the p-well region 1a to the deeper region of the p-well region 1a. The ion-implanted regions are kept in the non-amorphous state, and clusters of As are formed in the ion-implanted non-amorphous regions. A subsequent vertical ion-implantation of another n-type impurity such as P is carried out into the ion-implanted non-amorphous region having the As clusters in the p-well region 1a, thereby to form n-type deep source and drain regions 23 in the p-well region 1a. The ion-implanted P forms the other clusters with As in the ion-implanted non-amorphous region. Namely, other clusters of As and P are further formed in the ion-implanted non-amorphous regions. The ion-implanted regions correspond to the n-type deep source and drain regions 23. The ion-implanted regions have the clusters of As and the other clusters As and P. This means that surface regions of the n-type deep source and drain regions 23 have the clusters of As and the other clusters As and P. The clusters of As are formed in the ion-implanted non-amorphous regions corresponding to the n-type deep source and drain regions 23 by the prior ion-implantation process. Subsequently, when P is ion-implanted into the ion-implanted non-amorphous regions with the As clusters by the subsequent ion-implantation process, then P forms other clusters with As. Thus, the other clusters of As and P are formed in the n-type deep source and drain regions 23. Accordingly, the n-type deep source and drain regions 23 have the clusters of As and the other clusters of As and P. Namely, surface regions of the n-type deep source and drain regions 23 have the clusters of As and the other clusters As and P. Subsequently, the heat treatment such as the rapid thermal annealing process is carried out to activate the impurities. As described above, the n-type deep source and drain regions 23 have the clusters of As and the other clusters of As and P. Namely, surface regions of the n-type deep source and drain regions 23 have the clusters of As and the other clusters As and P. Both the clusters of As and the other clusters As and P serve to effectively suppress the outward diffusion of P, for example, the diffusion of P from the upper surfaces of the n-type deep source and drain regions 23. This suppression to the outward diffusion of P allows formation of the shallow junction diffusion regions. Further, the above-described rapid thermal annealing process for activation of the impurities in the diffusion regions causes enhanced oxidations of P and/or B, whereby surface oxide films over the upper surfaces of the n-type deep source and drain regions 23 and the p-type deep source and drain regions 25 are increased in thickness or amount. The surface oxide films over the upper surface of the n-type deep source and drain regions 23 suppress the outward diffusion of P, for example, the diffusion of P from the upper surfaces of the n-type deep source and drain regions 23 even if the oxygen concentration of the atmosphere for the rapid thermal annealing. This suppression to the outward diffusion of P by the surface oxide films allows keeping a low sheet resistance of the diffusion regions. This allows that not only the diffusion regions in the n-well region 1b but also the diffusion regions in the p-well region 1a have the reduced sheet resistance and the shallow junction.

Further, the prior vertical ion-implantation of an n-type impurity such as As is carried out, whereby ion-implanted regions are formed, which correspond to the n-type extension regions 28. The ion-implanted regions are kept in the non-amorphous state, and clusters of As are formed in the ion-implanted non-amorphous regions. A subsequent vertical ion-implantation of another n-type impurity such as P is carried out into the ion-implanted non-amorphous region having the As clusters in the p-well region 1a, thereby to form the n-type extension regions 28 in the p-well region 1a. The ion-implanted P forms the other clusters with As in the ion-implanted non-amorphous region. Namely, other clusters of As and P are further formed in the n-type extension regions 28. The ion-implanted non-amorphous regions correspond to the n-type extension regions 28. The n-type extension regions 28 have the clusters of As and the other clusters As and P. This means that surface regions of the n-type extension regions 28 have the clusters of As and the other clusters As and P. The clusters of As are formed in the ion-implanted non-amorphous regions corresponding to the n-type extension regions 28 by the prior ion-implantation process. Subsequently, when P is ion-implanted into the ion-implanted non-amorphous regions with the As clusters by the subsequent ion-implantation process, then P forms other clusters with As. Thus, the other clusters of As and P are formed in the n-type extension regions 28. Accordingly, the n-type extension regions 28 have the clusters of As and the other clusters of As and P. Namely, surface regions of the n-type extension regions 28 have the clusters of As and the other clusters As and P. Subsequently, the heat treatment such as the rapid thermal annealing process is carried out to activate the impurities. As described above, the n-type extension regions 28 have the clusters of As and the other clusters of As and P. Namely, surface regions of the n-type extension regions 28 have the clusters of As and the other clusters As and P. Both the clusters of As and the other clusters As and P serve to effectively suppress the outward diffusion of P, for example, the diffusion of P from the upper surfaces of the n-type extension regions 28. This suppression to the outward diffusion of P allows formation of the shallow junction diffusion regions. Further, the above-described rapid thermal annealing process for activation of the impurities in the diffusion regions causes enhanced oxidations of P and/or B, whereby surface oxide films over the upper surfaces of the n-type extension regions 28 and the p-type extension regions 31 are increased in thickness or amount. The surface oxide films over the upper surface of the n-type extension regions 28 suppress the outward diffusion of P, for example, the diffusion of P from the upper surfaces of the n-type extension regions 28 even if the oxygen concentration of the atmosphere for the rapid thermal annealing. This suppression to the outward diffusion of P by the surface oxide films allows keeping a low sheet resistance of the diffusion regions. This allows that not only the diffusion regions in the n-well region 1b but also the diffusion regions in the p-well region 1a have the reduced sheet resistance and the shallow junction.

In the above embodiment, As is implanted before P is then implanted. As a modification, it is possible that P is implanted before As is then implanted. In view of a possible reduction in mount or number of the crystal defects caused by the impurity implantation, it is preferable that As is implanted before P is then implanted in the above embodiment. The above implantation energies and the doses for the prior and subsequent ion-implantations for implanting As and P may be varied in accordance with the device rules, provided that the As-implanted regions are in the non-amorphous state to form the As-clusters and hen allow the later formation of other clusters of As and P upon later implantation of P. In the above embodiment, As is selected as the impurity which suppress the outward diffusion of P. In place of As, Ge and Ar are also available as the impurity which suppress the outward diffusion of P. Of course, two or three combinations of As, Ge and Ar may also be implanted as the impurities which suppress the outward diffusion of P.

In the above embodiment, As is implanted to form the n-type extension regions 28. As a further modification, it is possible that P, As₂, P₂, and combinations thereof are implanted to form the n-type extension regions 28. In the above embodiment, BF₂ is implanted to form the p-type extension regions 31. As a further modification, it is possible that B is implanted to form the p-type extension regions 31. In the above embodiment, B is implanted to form the deep p-type source and drain regions 25. As a further modification, it is possible that BF₂ is implanted to form the deep p-type source and drain regions 25. In the above embodiment, the side wall insulating films 33 comprise the single oxide film formed by the chemical vapor deposition method. As a further modification, it is possible that the side wall insulating films 33 comprise double layered structure or tripe layered structure of the oxide film and nitride film.

In the above embodiment, the substrate 1 is the silicon substrate 1. As a modification, it is possible that the substrate 1 comprises a silicon-on-insulator substrate or an epitaxial substrate. In the above embodiment, the gate insulating films 3a and 3b comprise the oxide films. As a modification, it is possible that the gate insulating films 3a and 3b comprise oxy-nitride films.

In accordance with the second novel method, it is unnecessary to form the cover film on the upper surface of the p-well region 1a for carrying out the heat treatment in the same oxygen atmosphere having the same oxygen concentration, because the As clusters and the As—P clusters suppress or prevent the outward diffusion of P. As a result, it is possible to form the shallow diffusion regions with the reduced sheet resistance even no cover film is selectively formed over the p-well region 1a. The oxygen concentration of the atmosphere, in which the heat treatment is carried out to activate the impurities, may preferably be in the range of 0.05 percents by volume to 1 percent by volume, wherein the surface oxide films are naturally formed over the upper surfaces of the diffusion regions, and the surface oxide films further contribute to suppress the outward diffusion of P. If the oxygen concentration of the atmosphere is lower than the above preferable range, then it might be possible that the suppression to the outward diffusion of P is imperfect, and the reduction in the sheet resistance of the diffusion regions is insufficient. If, however, the oxygen concentration of the atmosphere is higher than the above preferable range, then the oxygen enhanced diffusion of B or P is caused, thereby making it difficult to form the shallow junction. In the above embodiment, the cobalt silicide films are formed. As a modification, it is possible that other refractory metal silicide layers such as titanium silicide layers are formed.

Whereas modifications of the present invention will be apparent to a person having ordinary skill in the art, to which the invention pertains, it is to be understood that embodiments as shown and described by way of illustrations are by no means intended to be considered in a limiting sense. Accordingly, it is to be intended to cover by claims all modifications, which fall within the spirit and scope of the present invention.

What is claimed is:

1. A method of forming a diffusion region in a semiconductor region, said method comprising the steps of:
carrying out a first ion-implantation of a first impurity of a first conductivity type into the semiconductor region to form an ion-implanted region which is in non-amorphous state, wherein first type clusters of the first impurity are formed in the ion-implanted region;
carrying out a second ion-implantation of a second impurity of the first conductivity type into the ion-implanted region, wherein second type clusters of the first and second impurities are formed in the ion-implanted region; and
carrying out a heat treatment for activating the first and second impurities in the ion-implanted region to change the ion-implanted region into a diffusion region.

2. The method as claimed in claim 1, wherein the heat treatment is carried out in an oxygen atmosphere having an oxygen concentration in the range of 0.05 percents by volume to 1 percent by volume.

3. The method as claimed in claim 1, wherein the first impurity comprises at least one selected from the groups consisting of As, Ar and Ge, and the second impurity comprises P, and the first type and second type clusters suppress an outward diffusion of the second impurity of P in the heat treatment.

4. The method as claimed in claim 1, wherein the second impurity comprises at least one selected from the groups consisting of As, Ar and Ge, and the first impurity comprises P, and the first type and second type clusters suppress an outward diffusion of the first impurity of P in the heat treatment.

5. The method as claimed in claim 1, wherein the first impurity comprises As, and the second impurity comprises P, and the first ion-implantation is carried out at an implantation energy of less than 15 keV and a dose of less than 1E15 cm⁻².

6. The method as claimed in claim 1, wherein the diffusion region comprises an n-type extension region which extends in a p-type pocket implantation region which further extends in an upper region of an n-type deep source/drain region in a p-type semiconductor region.

7. The method as claimed in claim 6, wherein the p-type semiconductor region comprises a p-well region.

8. The method as claimed in claim 1, wherein the diffusion region comprises an n-type deep source/drain region in a p-type semiconductor region, and an upper region of the an n-type deep source/drain region overlapping an n-type extension region which extends in a p-type pocket implantation region.

9. The method as claimed in claim 8, wherein the p-type semiconductor region comprises a p-well region.

10. The method as claimed in claim 1, wherein the diffusion region comprises an n-type deep source/drain region in a p-type semiconductor region.

11. The method as claimed in claim 10, wherein the p-type semiconductor region comprises a p-well region.
